(19) United States
(12) Patent Application Publication
(10) Pub. No.: US 2017/0062172 A1
(43) Pub. Date: Mar. 2, 2017

(54) ELECTRON BEAM APPARATUS WITH ADJUSTABLE AIR GAP

(71) Applicant: Energy Sciences Inc., Wilmington, MA (US)

(72) Inventors: Imtiaz J. Rangwalla, Andover, MA (US); Rich Alexy, Auburndale, MA (US); Edward Maguire, North Andover, MA (US)

(21) Appl. No.: 15/246,821

(22) Filed: Aug. 25, 2016

Related U.S. Application Data
(60) Provisional application No. 62/209,951, filed on Aug. 26, 2015.

(51) Int. Cl. H01J 37/02; H01J 37/30

(52) U.S. Cl. CPC H01J 37/023; H01J 37/30

(57) ABSTRACT

An electron beam processing apparatus for treating a substrate is provided. The apparatus has an electron beam generating assembly housed in a chamber that includes a filament for generating a plurality of electrons upon heating. The apparatus may also have a foil support assembly that is configured to direct the plurality of electrons through a thin foil out of the chamber. The apparatus may further have a processing assembly that is configured to pass the substrate by the thin foil so that the plurality of electrons penetrates the substrate and cause a chemical reaction. A distance of an air gap between the thin foil and the substrate may be adjustable.

### TECHNICAL FIELD

The present disclosure is directed towards electron beam apparatuses, and more particularly, electron beam apparatuses having an adjustable air gap.

### BACKGROUND

An electron beam processing apparatus is commonly used to expose a substrate or coating to highly accelerated electrons, for example, in the form of an electron beam (EB), to cause a chemical reaction on the substrate or coating.

An electron is a negatively charged particle found in all matter. Electrons revolve around the nucleus of an atom much like planets revolve around the sun. By sharing electrons, two or more atoms bind together to form molecules. In EB processing, electron beams are used to modify the molecular structure of a wide variety of products and materials. For example, electrons can be used to alter specially designed liquid coatings, inks, rubbers, and adhesives. During EB processing, electrons break bonds and form charged electrons and free radicals. These radicals then combine to form large molecules. By this process, the liquid is transformed into a solid. This process is known as polymerization.

Liquid coatings treated with EB processing may include printing inks, varnishes, silicone release coatings, primer coatings, pressure sensitive adhesives, barrier coatings, barrier layers, and laminating adhesives. EB processing may also be used to alter and enhance the physical characteristics of solid materials such as paper, plastic films, substrates (including, e.g., non-woven textile substrates), and polymeric materials (such as elastomers), all specially designed to react to EB treatment.

An electron beam processing apparatus may generally include three zones. A vacuum chamber zone where the electron beam may be generated, an electron accelerator zone, and a processing zone. In the vacuum chamber, a tungsten filament may be heated to about 2400 K, which is the electron emission temperature of tungsten, to create a cloud of electrons. A positive voltage differential may then be applied to the vacuum chamber to extract and simultaneously accelerate these electrons. Thereafter, the electrons may pass through a thin foil and enter the processing zone. The thin foil functions as a barrier between the vacuum chamber and the processing zone. Accelerated electrons exit the vacuum chamber through the thin foil and enter the processing zone at atmospheric conditions.

The accelerated electrons that enter the processing zone are directed to the substrate that is to be treated. Between the thin foil support assembly and the drum or other apparatus that supports the substrate is an air gap, which the electrons cross to reach the substrate. The distance of the air gap for an electron beam system is fixed based on the positioning of the electron beam apparatus and the processing assembly (e.g., rollers or drums feeding the substrate). The air gap distance may be set based on several intended processing variables, for example, the operating voltage, product, processing speed, etc.

More recently, electron beam processing apparatuses have been developed that operate at both lower voltage (e.g., 110 kV or less) and higher voltage (e.g., 110 kV or greater) at increased efficiency. Some examples of these systems are described in U.S. Pat. Nos. 6,426,507; 6,610,376; 7,026,635; and 7,348,580, which are incorporated herein by reference in their entireties.

Despite the advances and improvements in electron beam processing apparatuses, a need exists for more versatile electron beam processing apparatuses capable of maintaining efficiency when operating at both high and low voltage and capable of maintaining efficiency processing a variety of products. The present disclosure is directed to improved electron beam processing apparatuses and method of operation.

### SUMMARY

In one embodiment, the present disclosure is directed to an electron beam processing apparatus for treating a substrate. The apparatus may include an electron beam generating assembly housed in a chamber that includes a filament for generating a plurality of electrons upon heating. The apparatus may also include a foil support assembly that is configured to direct the plurality of electrons through a thin foil out of the chamber. The apparatus may further include a processing assembly that is configured to pass the substrate by the thin foil so that the plurality of electrons penetrates the substrate and causes a chemical reaction. A distance of an air gap between the thin foil and the substrate is adjustable.

In another embodiment, the present disclosure is directed to a method of treating a substrate with an electron beam processing apparatus. The method may include generating a plurality of electrons using an electron beam generating assembly by heating a filament within a chamber of the assembly. The method may also include directing the plurality of electrons out of the chamber and through a thin foil located within a foil support assembly. The method may further include feeding the substrate into a processing assembly and passing the substrate in front of the thin foil so that the plurality of electrons penetrates the substrate and causes a chemical reaction. The method is also to include adjusting a distance of an air gap between the thin foil and the substrate.

In another embodiment, the present disclosure is directed to an electron beam processing apparatus for treating a substrate having an adjustable air gap.

The accompanying drawings, which are incorporated in and constitute a part of this specification, illustrate several embodiments of the present disclosure and together with the description, serve to explain the principles of the present disclosure.

### BRIEF DESCRIPTION OF THE DRAWINGS

FIG. 1 is a schematic view of a portion of an electron beam processing apparatus according to an exemplary embodiment;

FIG. 2 is a schematic view of a voltage profile of an electron beam;

FIG. 3 is a schematic view of a portion of an electron beam processing apparatus according to an exemplary embodiment;

FIG. 4 is a plot of depth dose for two different air gap distances;

FIG. 5 is a plot of depth dose for two different operation voltages;

FIG. 6 is a schematic view of a portion of an electron beam processing apparatus according to an exemplary embodiment; and

FIG. 7 is a schematic view of a portion of an electron beam processing apparatus according to an exemplary embodiment.

### DETAILED DESCRIPTION

The term “about” or “approximately” as used herein means within an acceptable error range for the particular value as determined by one of ordinary skill in the art, which will depend in part on how the value is measured or determined, e.g., the limitations of the measurements system. For example, “about” can mean within one or more than one standard deviation per the practice in the art. Alternatively, “about” can mean a range of up to 20%, such as up to 10%, up to 5%, and up to 1% of a given value.

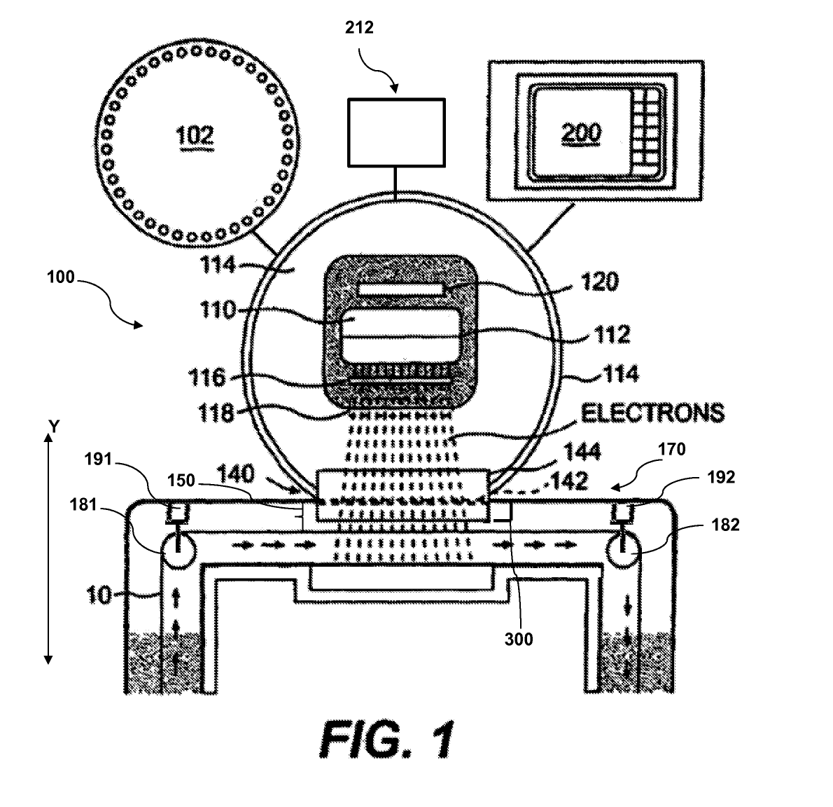

FIG. 1 schematically illustrates an electron beam processing apparatus 100, according to an exemplary embodiment. Electron beam processing apparatus 100 may include a power supply 102, an electron beam generating assembly 110, a foil support assembly 140, and a processing assembly 170. Power supply 102 may be configured to supply power at a wide range of operating voltages. For example, in some embodiments, power supply 102 may supply power at about 110 kV or less (e.g., low voltage) or in some embodiments power supply 102 may supply power at about 110 kV or more (e.g., high voltage). In some embodiments, power supply 102 may provide about 110 kV to 300 kV to processing apparatus 100. In some embodiments, power supply 102 may provide about 60 kV to 110 KV to processing apparatus 100. Power supply 102 may be of a commercially available type that includes multiple electrical transformers located in an electrically insulated steel chamber to provide a high voltage to electron beam generating assembly 110 to produce electrons.

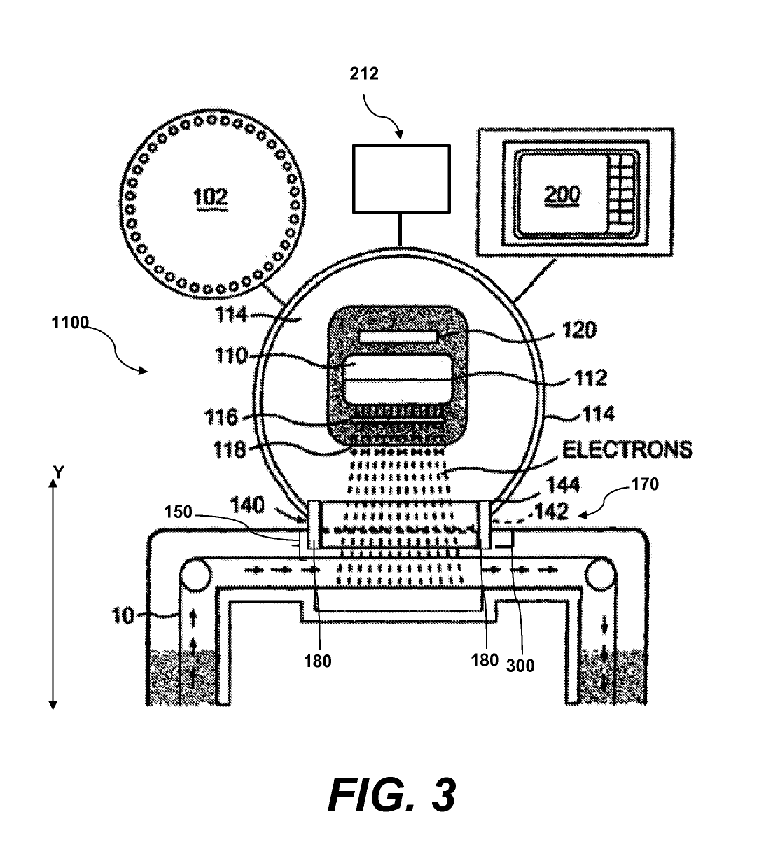

Electron beam generating assembly 110 may be kept in a vessel or chamber 114 that is a vacuum environment. Chamber 114 may be constructed of a tightly sealed vessel. A vacuum pump 212 (shown in FIG. 3) may be provided to create the vacuum environment in the order of approximately 10⁻⁶ Torr. Inside the vacuum environment of chamber 114, a cloud of electrons may be generated around filament 112 by sending electrical power from power supply 102 to filament 112, thereby causing filament 112 to heat up.

When heated, filament 112 may glow white hot and generate a cloud of electrons. Because the electrons are negatively charged, the electrons may be drawn from filament 112 to areas of higher voltage and accelerated to extremely high speeds. In some embodiments, filament 112 may be constructed of one or more wires, which may be made, for example, of tungsten.

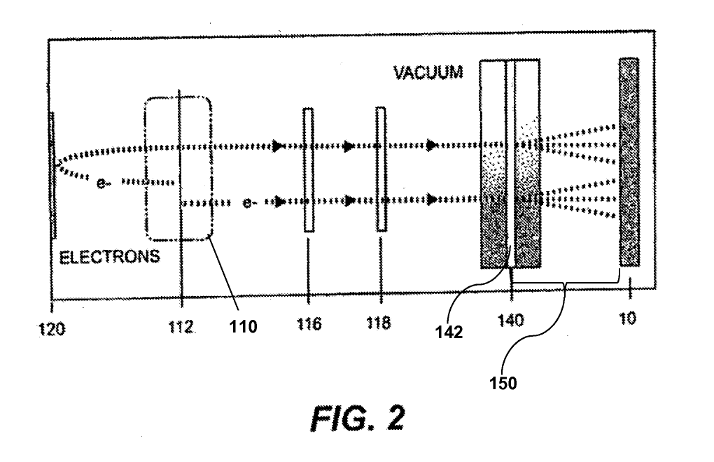

As shown in FIGS. 1 and 2, electron beam generating assembly 110 may include an extractor grid 116, a terminal grid 118, and a repeller plate 120. Repeller plate 120 may be configured to repel electrons toward extractor grid 116. Repeller plate 120 may operate at a different voltage, for example, slightly lower than that of filament 112, to collect electrons escaping from filament 112 away from the intended direction of the electron beam, as shown in FIG. 2.

Extractor grid 116 may operate at a slightly different voltage, for example, higher than that of filament 112. Extractor grid 116 may attract electrons away from filament 112 and guide them toward terminal grid 118. Extractor grid 116 may be configured to control the quantity of electrons being drawn from the cloud, which determines the intensity of the electron beam.

Terminal grid 118 may operate generally at the same voltage as extractor grid 116, and terminal grid 118 may be configured to act as the final gateway for electrons before they accelerate to extremely high speeds for passage through foil support assembly 140.

As shown in FIGS. 1 and 2, electron beam processing apparatus 100 may be configured such that electrons that exit vacuum chamber 114 may pass through foil support assembly 140, wherein the electrons may pass through thin foil 142 and be directed to processing assembly 170, where the electrons penetrate substrate 10, causing a chemical reaction. The chemical reaction may include, for example, polymerization, cross-linking, or sterilization. In some embodiments, the speed of the electrons may be as high as or above 100,000 miles per second. Foil support assembly 140 may be made up of a series of parallel copper ribs (not shown). Thin foil 142, as shown in FIG. 1, may be securely clamped to the outside of foil support assembly 144 and may be configured to provide a leak-proof vacuum seal inside chamber 114.

High-speed electrons may pass freely between the copper ribs, through thin foil 142, and into substrate 10 being treated. To minimize undue energy loss, thin foil 142 may be made as thin as possible while at the same time providing sufficient mechanical strength to withstand the pressure differential between the vacuum state inside chamber 114 and ambient conditions for processing assembly 170. In some embodiments, thin foil 142 of the foil support assembly may be made of, for example, titanium or alloys thereof and may have a thickness of about 12 micrometers or less (e.g., 10 micrometers, 9, micrometers, or 8 micrometers). In some embodiments, thin foil 142 may be constructed of aluminum or alloys thereof and may have a thickness of about 15 micrometers or less.

Processing assembly 170 may include a plurality of components and mechanisms configured to direct substrate 10 past thin foil 142. A protective lining may surround the periphery of processing device 100, such as evacuated chamber 114 and processing assembly 170. The protective lining may be configured to absorb substantially all X-rays created when electrons decelerate in matter. The thickness and material selected for the protective lining may be determined, at least in part, by the desired absorption rate of the X-rays.

Dose is the energy absorbed per unit mass and is measured in terms of megarads (Mrad), which is equivalent to 2.4 calories per gram. A higher number of electrons absorbed reflect a higher dose value. In application, the desired dose is commonly determined by the material of the coating and the depth of the substrate to be cured. For example, a dose of 5 Mrad may be required to cure a coating on a substrate that is made of rice paper and has a mass density of 20 gram/m². Alternatively, a dose of 7 or 10 Mrad may be required to cure a substrate that is made of rubber and has a mass density of about 1000 gram/m² or about 2000 gram/m², respectively. Dose is directly proportional to the operating beam current, which is the number of electrons extracted, and inversely proportional to the feed speed of the substrate, as expressed by the following formula:

Dose=K·(I/S)

whereby I is the current measured in mAmp, S is the feed speed of the substrate measured in feet/min, and K is a proportionality constant, which represents a machine yield of the processing device, or the output efficiency of that particular processing device.

The amount of dose delivered and the location of dose delivery may be manipulated by adjusting a variety of variables, for example, the thickness of the thin foil, the size of the air gap, and the voltage at which the electron beam processing apparatus is operated. The desired dose amount and location may be calculated based on the substrate and use of the assembly. For example, a low operation voltage is usually used in conjunction with thinner foils to cure the surface of thinner substrates. With a lower voltage, the electrons move at slower speeds, and with a smaller air gap and thinner foil, less electron energy losses in air will occur in the foil and the air gap. This will result in a higher deposition of dose and thus yield efficiency at the surface and shallower dose penetration in the substrate. By contrast, higher operation voltages are usually used for thicker substrates to achieve a lower surface dose and deeper dose penetration. With higher voltages, energy loss is less of a concern, so a larger air gap and thicker foil can be used to decrease the surface dose and increase the dose delivered at a deeper substrate depth.

FIG. 1 shows one embodiment of a processing assembly 170, which includes, among other things, at least a first roller 181 and a second roller 182 configured to feed substrate 10 by thin foil 142. As shown in FIG. 1, the positioning of processing assembly 170 (e.g., rollers 181 and 182) and the positioning of foil support assembly 140 (e.g., thin foil 142) relative to one another may define a distance 150 between thin foil 142 and substrate 10. Distance 150 may be referred to herein as the air gap and/or product gap.

The electrons accelerated through thin foil 142 may cross air gap 150 before penetrating substrate 10. As the electrons travel across air gap 150, the air present may become heated due to electrons being stopped in the air and energy transfer taking place resulting in heat increase from the slowing and stopping of electrons. The temperature of the air within air gap 150, which is adjacent thin foil 142, may affect the life of thin foil 142. For example, if the air temperature in air gap 150 becomes extremely hot, it may reduce the life of thin foil 142, leading to premature failure. The air temperature in air gap 150 may depend on a variety of parameters, including for example, the speed of the electrons and the distance of air gap 150. For example, the greater the distance of air gap 150, the hotter the air temperature due to the increased heat created by low energy electrons being stopped and slowed down as they pass over the distance of air gap 150. Additionally, as the electrons travel through air, they may stop and/or slow down and lose energy due to momentum transfer. Therefore, a larger air gap will increase the distance the electrons must travel through air, resulting in a greater loss of electron energy over that distance, whereas a smaller air gap will reduce the distance travelled by the electrons, resulting in a smaller loss of energy.

Other factors may also be considered in determining a suitable air gap 150 distance for an electron beam processing apparatus 100. For example, a minimum air gap 150 may be established based on substrate 10. For example, the minimum air gap 150 distance between foil 142 and substrate 10 may be such that substrate 10 may pass by thin foil 142 without interfering or contacting thin foil 142 and/or foil support assembly 140. The minimum air gap 150 may vary based on the type of substrate 10 and/or the thickness of substrate 10. The operating voltage (chosen because of certain penetration depth requirements in the substrate for some applications) of particle beam generating assembly 110 may also be another factor considered in determining the air gap 150 for an electron beam processing apparatus 100. For example, at lower voltages (e.g., 110 kV to 125 kV), it may be preferable to have a reduced air gap 150 to minimize energy losses in air of electrons. At lower voltages, because of shallow electron energy depth requirement, energy loss due to air gap distance may be of greater concern. In contrast, at high voltages (e.g., 125 kV to 300 kV) energy losses in air of electrons may be less of a concern, and thus the distance of air gap 150 may be increased. In some embodiments, for higher voltages, increased air gap may be desired to maximize efficiency (K-value) resulting in higher product speed at fixed dose.

Traditional electron beam processing apparatuses have an air gap 150 of a fixed, pre-determined distance. The distance of air gap 150 may be calculated at time of system design based on the intended use of that particular apparatus. For example, the ideal air gap may be calculated based on intended substrate product which fixes the operating voltage, to maximize efficiency (K-value) to allow desired commercial speed of process, and the apparatus is built to reflect the air gap calculated for those specific criteria. As a result, if any of the parameters are later changed, for example, the substrate and the depth to cure the substrate and thus the desired operating voltage change, the distance of air gap 150 may no longer be optimal for the new product or operating voltage, thereby causing a loss in efficiency.

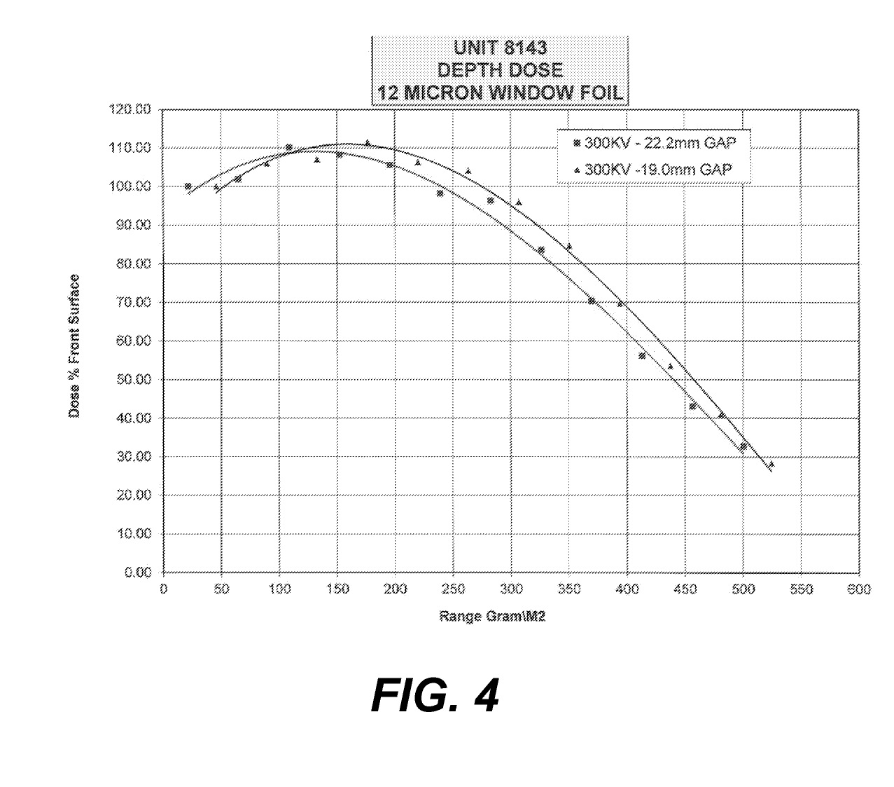

In the example shown in FIG. 4, a traditional electron beam processing apparatus having an air gap of 22 mm and a thin foil with a thickness of 12 microns may operate at 300 KV to cure a product at a depth of 250 grams/m². Under those conditions, the user may achieve a 100% dose at the surface of the substrate and a 100% dose at a depth of 250 grams/m². However, due to market changes, the substrate product may need to be changed, for example, increased by 25 grams/m², increasing the total thickness to 275 grams/m². To maintain a 100% dose at 275 grams/m², traditionally the voltage applied would need to be increased or the thin foil of a different thickness would need to be installed to recover at least some of the loss in efficiency. However, adjusting the voltage setting may not be possible if the system was already operating at a maximum voltage (e.g., 300 kV) and changing the thin foil may be undesirable because changing the thin foil is time intensive (e.g., 4 to 6 hours), and shutdown of the system to replace the thin foil is not economically viable (e.g., due to loss in production time).

Electron beam processing apparatus 100, according to an exemplary embodiment, resolves this issue by being configured such that the distance of air gap 150 is adjustable. The ability to adjust air gap 150 broadens the penetration ranges that may be achieved using a single apparatus 100 and does so while optimizing production speeds and machine uptime. Using electron beam processing apparatus 100 may allow a user to easily adjust air gap 150 to meet the new product requirements. For example, using processing apparatus 100, the air gap may be adjusted to 19 mm and the apparatus may then operate 300 kV with a thin foil 142 thickness of 12 microns, which may obtain 100% dose at a depth of 275 gram/m², as shown in FIG. 4.

In FIG. 4, the x-axis shows the depth of penetration, and the y-axis shows how much energy the electron is losing. It is noted that the slope of the curve changes with the change in the air gap. As described herein, thin foil 142 may be replaced with a thin foil of a different thickness to recover at least some of the loss in efficiency, but changing the thin foil is time intensive (e.g., 4 to 6 hours), and shutdown of the system to replace the thin foil is undesirable (e.g., due to loss in production time) and not commercially viable. If the air gap is adjusted to 19 mm, it provides greater penetration and helps lower voltages by increasing surface electron absorption by reducing air losses, and increasing the machine yield to cure thin inks and coatings in the 10-15 grams/m² range, restricting electron beam penetration in the substrate.

For some applications, a product substrate may require a very shallow electron penetration requiring less than 100 kV, e.g., because the product requires just surface dose and very limited penetration in the substrate. For some electron beam processing systems, if the minimum operating range is 100 kV this could create a challenge. However, process apparatus 100 as described herein may increase the air gap, thereby one may effectively limit electron penetrate to less than 100 kV, even though the minimum machine capability is 100 KV.

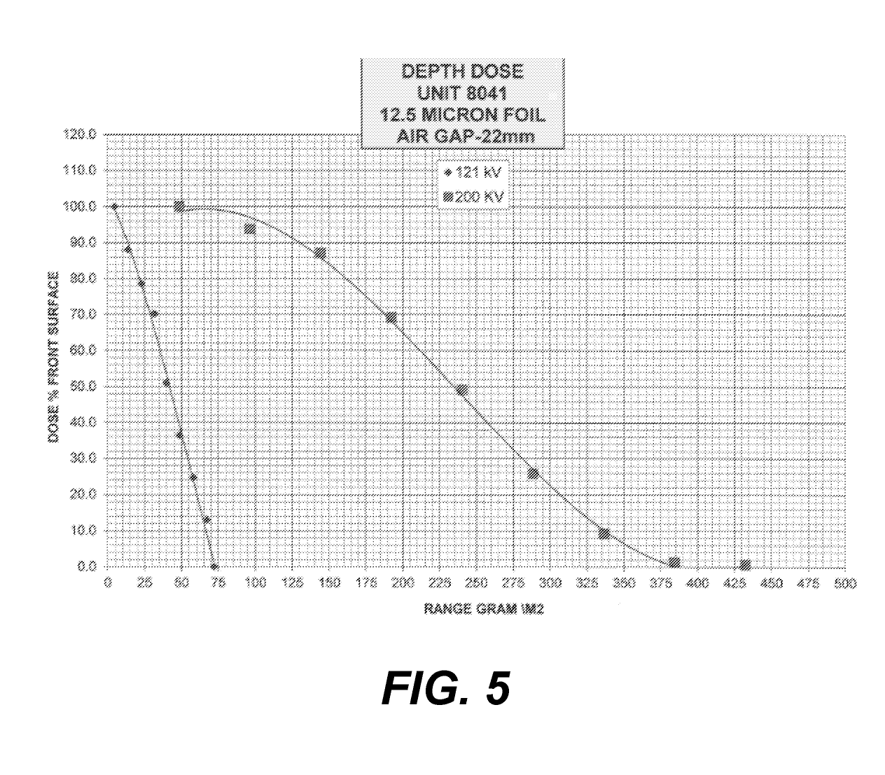

FIG. 5 demonstrates additional shortcomings of a traditional fixed air gap electron beam processing apparatus. This traditional electron beam processing apparatus operates at 100 to 200 kV EB, has a fixed air gap of 22 mm and uses a 12.5 micron foil. Operating at 200 kV to cure an adhesive 100 grams/m² thick at these conditions may absorb a dose of >95% at 100 grams/m². The user of this apparatus may also have another product that needs to be cured at a lower operating voltage of 121 kV again due to shallow electron penetration requirements. In this case, the user may cure a 20 grams/m² adhesive on a very radiation-sensitive substrate located at a depth of 75 grams/m². The deeper base substrate may not be able to tolerate any radiation. As is shown in FIG. 5, operating the machine at 121 kV achieves the required dose of 80% at 20 grams/m² while administering zero dose at 75 grams/m². However, if the air gap were reduced to 19 mm for this low-voltage operation, then the energy losses in air at these low voltages would be minimized, which would increase the machine efficiency by increasing the surface dose resulting in higher product speeds making it more commercially viable. And, at the same time, the slope of the depth dose profile would be steeper, restricting the dose to almost zero at a depth of 75 grams/m². Accordingly, it would be more economical to adjust the air gap as opposed to changing thin foil because of the substantial down time.

For example, using electron beam processing apparatus 100 with a 12.5 micron foil at an air gap of 19 mm and a voltage of 121 kV would produce a yield of 1 normalized, as measured by dosimetry. On the other hand, using a 12.5 micron foil with an adjusted air gap of 22 mm and a voltage of 121 kV would produce a yield dose of 0.9 normalized, as measured by dosimetry. Accordingly, in this example, reducing the air gap would increase the machine efficiency increased by 10% when operating at 121 kV.

In another example, to optimize the machine efficiency at 100 grams/m² at 200 kV on the same machine, the air gap could be increased. In one example, machine efficiency, as measured by dosimetry results, would be 1.07, normalized, using a 12.5 micron foil with an air gap of 22 mm and a voltage of 200 kV. Using a 12.5 micron foil with an air gap of 19 mm and a voltage of 200 kV on the same machine would result in an efficiency of 1.0, normalized. In this example, the electrons may have more energy when approaching the product substrate using a reduced air gap than the electrons would otherwise have with a higher air gap. With a reduced air gap, the electrons would have less of a propensity to slow or stop and instead would deposit the dose when meeting the substrate rather than continue to move through the substrate. As a result, the machine yield would be higher at 200 kV with a higher air gap than with a lower air gap. The opposite would be seen with a low voltage, in which the electrons would slow when moving across the larger air gap and would deposit when meeting the substrate surface. Thus requiring adjustable air gap on these versatile EB machines varying from low voltages 70 kV to higher voltages 300 kV as determined by various product requirements and its electron penetration depths.

In some situations, a manufacturer using an electron beam processing apparatus may know from the start they are going to process a variety of different substrates requiring different depths of electron penetration and thus requiring operating at a variety of different voltages. In these situations, the distance of the air gap has traditionally been calculated based on one substrate type its electron depth requirement and thus the voltage, or the distance of the air gap may be calculated based on an average of the substrate types and average depth requirements and thus the voltages. However, regardless of the method in used to calculate the distance of the air gap, at times the apparatus will be operating at a less-than-optimal air gap, which reduces efficiency.

As described herein, an electron beam processing apparatus with a permanently set gap can broaden the depth of penetration ranges by changing the voltage applied, but simply changing the voltage to attain different depth of penetration ranges will also affect production speed and foil life, which ultimately shortens yield. One may operate at lower depths of penetration and thus lower voltages, for example with a 12.5 micron foil, but as taught in earlier patents, the energy absorbed by the foil at these lower voltages will increase substantially. This will result in premature foil failure unless one restricts the mA resulting and in combination with lower yields will result in lower product speeds making this technology not commercially viable. As described herein, another option is to change the thin foil thickness by changing the window foils as various substrates are processed, but as described herein, changing the window foil is time consuming.

Electron beam processing apparatus 100, according to an exemplary embodiment, resolves this issue by being configured such that the distance of air gap 150 is adjustable. The ability to adjust air gap 150 broadens the penetration ranges that may be achieved using a single apparatus 100 and does so while optimizing production speeds and machine uptime. Being able to vary the distances between thin foil 142 and substrate 10, along with changing the voltage applied, makes apparatus 100 able to more closely control the dose of energy delivered and the dose penetration depth with a single apparatus, while also allowing for differences in heat loads, production speed, and up-time yield. By doing so, apparatus 100 may efficiently accommodate a variety of substrate types and uses. Apparatus 100 may enable broader processing capabilities for multitudes of products that each requires different depths of dose penetration and energy in a manner that cannot be achieved using current technology.

In some embodiments, the distance of air gap 150 may be adjustable by changing the positioning of one or more components of processing assembly 170. In some embodiments, the distance of air gap 150 may be adjustable by changing the positioning of substrate 10 relative to thin foil 142 such that the position of substrate 10 changes while the positioning of thin foil 142 stays the same. In some embodiments, the distance of air gap 150 may be adjustable by changing the position of thin foil 142 such that the position of thin foil 142 changes, while the positioning of substrate 10 remains the same. In some embodiments, the distance of air gap 150 may be adjustable by changing the position of both thin foil 142 and one or more other components of processing assembly 170.

In some embodiments, when apparatus 100 is curing a product that is about 50 gram/m² thick, it may be desirable to reduce the voltage to, for example, 150 kV, to reduce the velocity and kinetic energy of the electrons. Correspondingly, apparatus 100 may be configured to also reduce the distance of air gap 150 so that the energy loss in the air is less, thereby increasing the surface dose and enabling optimization of the dose on the surface. This optimization may allow for increased production speed, which is typically desired. In some embodiments, apparatus 100 operating at even lower voltages (e.g., about 110 kV and 60-70 kV) with a 10 micron and 5 micron thin foil 142 thickness, the efficiency and dose may be increased by 20-30%. This may be attributed to changing of the scattering angle of the electrons. Scattering angle is described in detail in U.S. Pat. No. 4,952,814, which is incorporated herein by reference in its entirety.

In some embodiments, apparatus 100 having a thin foil 142 thickness of 10 microns may be configured to have an air gap 150 of about 9.5 mm when operating at a voltage of between about 100 kV to about 125 kV and may have an air gap 150 of about 7.5 mm when operating at a voltage between about 60 kV to about 100 KV. In some embodiments, apparatus 100 having a thin foil 142 thickness of 12.5 microns may be configured to have an air gap 150 of about 9.5 mm when operating at a voltage of between about 100 kV to about 150 kV and an air gap 150 of about 19 mm when operating at a voltage between about 150 kV to about 200 kV. In some embodiments, apparatus 100 having a thin foil 142 thickness of 12.5 microns may be configured to have an air gap 150 of about 9.5 mm when operating at a voltage between about 125 kV and 150 kV and an air gap 150 of about 19 mm when operating at a voltage between about 150 kV and 300 kV. It is contemplated that other air gap 150 distances and ranges of operation (e.g., voltages, and thin foil thickness) may be utilized depending on a number of variables (e.g., substrate type, substrate thickness, desired speed of operation, etc.).

Electron beam processing apparatus 100, as shown in FIG. 1, may be configured to adjust the distance of air gap 150 by adjusting the position of one or more components of processing assembly 170. For example, processing assembly 170 may include first roller 181 and a second roller 182 that may be configured to determine the elevation at which substrate 10 passes by thin foil 142, thereby determining the distance of air gap 150. In some embodiments, as shown in FIG. 1, substrate 10 may wrap around first roller 181 about 25% of the way, thereby making a turn of about 90 degrees and running beneath particle beam generating assembly 110 and thin foil 142 until it reaches second roller 182, where it may wrap around about 25% of the way and make another 90 degree turn. While two rollers 181, 182 are depicted, it is contemplated that more than two rollers or fewer that two rollers may be utilized to direct substrate 10. In some embodiments, a conveyer belt may also be used in conjunction with one or more rollers.

First roller 181 and second roller 182 may include a first adjustment mechanism 191 and a second adjustment mechanism 192 attached to first roller 181 and second roller 182. First adjustment mechanism 191 and second adjustment mechanism 192 may be configured to adjust the position of first roller 181 and second roller 182, respectively. For example, first adjustment mechanism 191 and second adjustment mechanism 192 may be actuators configured to adjust the positioning of first roller 181 and second roller 182 along an axis Y. First adjustment mechanism 191 and second adjustment mechanism 192 may be, for example, hydraulic actuators, pneumatic actuators, electrical actuators, or any other suitable type of actuator. When pneumatic actuators are used, the compressed air may be supplied by a pneumatic system within the processing or manufacturing facility.

FIG. 3 shows another exemplary embodiment of an electron beam processing apparatus 1100 that may be configured to provide for an adjustable distance of air gap 150. Apparatus 1100 may be substantially the same as apparatus 100, described herein, except that apparatus 1100 may be configured to adjust the position of thin foil 142 rather than adjusting the position of substrate 10. For example, foil support assembly 140 may include an adjustment mechanism 180 configured to adjust the positioning of foil support assembly 140 and thin foil 142 along axis Y. Adjustment mechanism 180 may utilize, for example, hydraulic, pneumatic, electrical actuators, or other similar actuation. Foil support assembly 140 and chamber 114 may be coupled to allow movement of foil support assembly 140 along axis Y while maintaining integrity of the vacuum within chamber 114. In some embodiments, an electron beam processing apparatus may include both adjustment mechanisms for adjusting the positioning of the rollers as well as an adjustment mechanism for adjusting the positioning of the thin foil, thereby enabling adjustment by moving the thin foil, the substrate, or both. Accordingly, an apparatus may include only adjustment mechanisms 191, 192 to adjust substrate 10; only adjustment mechanism 180 to adjust thin foil 142; or both adjustment mechanisms 191, 192, and 180 to adjust both substrate 10 and thin foil 142. Additionally, the types of adjustment mechanisms may be the same (e.g., pneumatic, hydraulic, electric) or the adjustment mechanisms may be different. In some embodiments, only one component may be adjusted at a time, but the apparatus may be configured to allow either thin foil 142 or substrate 10, for example, for redundancy or based on any other parameters.

Electron beam processing apparatus 100, 1100 may further include a controller 200, such as a computerized microprocessor, to control operation of apparatus 100, 1100. Controller 200 may be configured to control several processes including but not limited to maintaining the required vacuum environment within chamber 114, receiving inputs from an operator, initiating system operation with predetermined voltages and filament power, synchronizing electron generation with process speed to maintain constant treatment level, monitoring functions and interlocks, controlling adjustment mechanisms (e.g., 191, 192, 180) to set the distance of air gap 150, and providing warnings and/or alarms whenever the system functions exceed set limits or an interlock problem is detected. Adjustment mechanisms may be manual or automated. For example, a user may input substrate parameters, and apparatus 100, 1100 may automatically be adjusted. Some embodiments may include one or more sensors that are configured to detect one or more characteristics substrate 10 or apparatus 100, 1100 and may automatically make adjustments based on those characteristics. Even if automatic, however, apparatus 100, 1100 may include a manual override.

In some embodiments, apparatus 100, 1100, may further include a temperature sensor 300 that generates a signal indicative of an air temperature within air gap 150, and temperature sensor 300 may be configured to transmit the signal to controller 200. In some embodiments, controller 200 may be configured to adjust the distance of air gap 150 based on the signal from sensor 300. Apparatus 100, 1100 may also include other sensors, e.g., those configured to detect a weight or thickness of a substrate or an actual operating voltage of the apparatus.

In some embodiments, electron beam processing apparatus 100, 1100 may operate as follows. Vacuum pump 212 may evacuate air from chamber 114 to achieve a vacuum level of approximately 10⁻⁶ Torr, at which point processing apparatus 100 may be fully operational. Electron generating assembly 110, including repeller plate 120, extractor grid 116, and terminal grid 118, may be set at three independently controlled voltages that initiate the emission of electrons and guide their passage through foil support 144 and thin foil 142. Controller 200 may be configured to control the voltages of repeller plate 120, extractor grid 116, and/or terminal grid 118. In some embodiments, an operator may manually input the voltages, or in some embodiments, an operator may input just one operating voltage and controller 200 may automatically determine the independent operation voltages of the different components. In some embodiments, an operator may just input a substrate type and/or operating speed and controller 200 may determine the operating voltages based on that input.

Operation of apparatus 100, 1100 may also include adjusting the distance of the air gap between thin foil 142 and substrate 10, as discussed herein. The distance of air gap 150 may be adjusted, for example, prior to the start of operation. In some embodiments, the distance of air gap 150 may be adjusted during operation. In some embodiments, controller 200 may be configured such that a set point for the distance of air gap 150 may be determined based on at least one of an operating voltage for the electron beam generating assembly, the type of substrate 10, the thickness of substrate 10, and/or the desired speed of production (i.e., speed of substrate 10). In some embodiments, an operator may input or set the distance of air gap 150 using controller 200. In some embodiments, an operator may input the type of substrate 10 into controller 200, and controller 200 may be configured to automatically determine an optimal operating voltage and an optimal distance of air gap 150. In some embodiments, controller 200 may also regulate the quantity of electrons generated so the electron beam output is proportional to the feeding speed of substrate 10. Electron beam processing apparatus 100, 1100 may be calibrated to achieve high-precision specification, because controller may provide the exact depth level of cure desired on substrate 10. Controller 200 may calculate the dose and the depth of electron penetration into substrate 10. The higher the voltage, the greater the electron speed and resultant penetration.

During the electron beam processing, a combination of electric fields inside evacuated chamber 114 may create a “push/pull” effect that guides and accelerates the electrons toward thin foil 142 of foil support 144, which is at ground (0) potential. The quantity of electrons generated may be directly related to the voltage of extractor grid 116. At slow production speeds, extractor grid 116 may be set at a lower voltage (e.g., by controller 200) than at high speeds, when greater voltage may be applied. As the voltage of extractor grid 116 increases, the quantity of electrons being drawn from filament 112 may also increase.

The coatings to be cured, for example, inks, adhesives, and other coatings, generally require a low-oxygen environment to cause the chemical conversion from a liquid state into a solid state. Therefore, in some embodiments, electron beam processing apparatus 100, 1100 may also include a plurality of nozzles (not shown) distributed in processing assembly 170 to inject gas (other than oxygen) to displace the oxygen therein. In some embodiments, nitrogen gas may be pumped into processing assembly 170 through the plurality of nozzles to displace the oxygen that would otherwise prevent or inhibit complete curing.

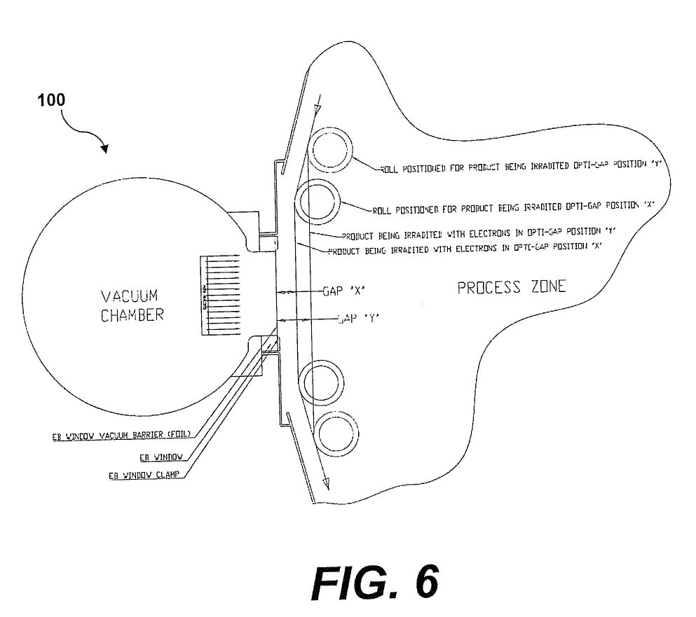

FIG. 6 shows another exemplary embodiment of an electron beam processing apparatus 100. Apparatus 100 shown in FIG. 6 is substantially similar to apparatus 100 described in reference to FIG. 1. Apparatus 100 as shown in FIG. 6 may include, for example, a non-chill roll system having a pair of rollers than may be adjusted between a position X and a position Y, and movement of the rollers from position X to position Y or vice versa changes (i.e., adjusts) the distance of the air gap 150, creating an air gap X and an air gap Y distance, as shown in FIG. 6. In some embodiments, the non-chill roll system may be configured such that the substrate is parallel to the thin foil as it passes by the thin foil.

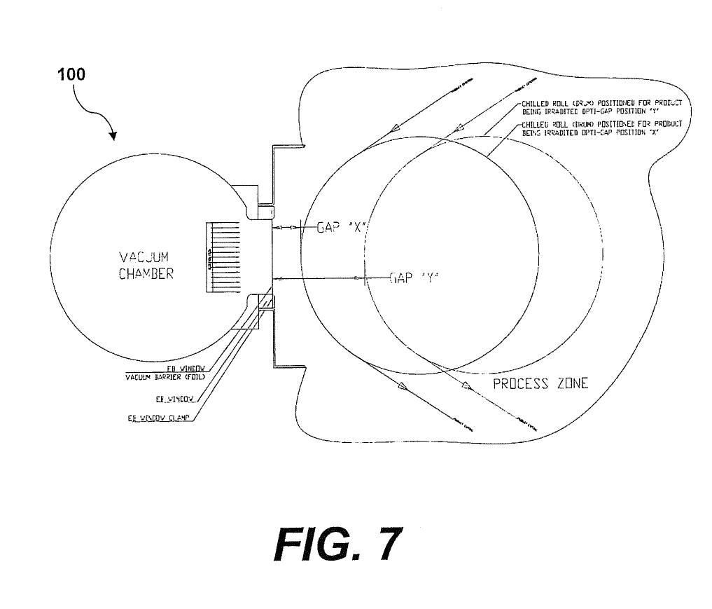

FIG. 7 shows another exemplary embodiment of an electron beam processing apparatus 100. Apparatus 100 shown in FIG. 7 may be substantially similar to apparatus 100 as shown in FIG. 1, except that processing assembly or “the processing zone” of the embodiment in FIG. 7 may utilize for example, a chill drum having a single, larger roller to pass the substrate by the thin foil. Accordingly, the air gap may be adjusted by adjusting the position of the larger roller. The single, larger roller may be adjusted, for example, between an X position and a Y position to produce an air gap X and an air gap Y distance. In some embodiments, the chill drum may be configured such that the substrate follows the contours of the arc of the chill drum rather than passing by parallel to the thin foil.

In each of the embodiments described herein, apparatus 100, 1100 may be adjustable along discrete, pre-determined intervals, or may be adjustable along a continuous range of distances. In some embodiments, apparatus 100, 1100 may have a maximum and/or minimum air gap distance beyond which the apparatus cannot be adjusted. For embodiments incorporating a controller, apparatus 100, 1100 may be adjustable by a user on-site and/or a user may be able to adjust the apparatus from a remote locations.

Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims and their equivalents.

What is claimed is:

1. An electron beam processing apparatus for treating a substrate, comprising:
an electron beam generating assembly housed in a chamber that includes a filament for generating a plurality of electrons upon heating;
a foil support assembly that is configured to direct the plurality of electrons through a thin foil and out of the chamber;
a processing assembly that is configured to pass the substrate by the thin foil so that the plurality of electrons penetrates the substrate and causes a chemical reaction on the substrate; and
an air gap located between the thin foil and the substrate, wherein a distance of the air gap is adjustable.

2. The apparatus of claim 1, wherein the processing assembly includes one or more rollers configured to pass the substrate by the thin foil, and wherein the distance of the air gap is adjustable by changing the position of the one or more rollers relative to the thin foil.

3. The apparatus of claim 2, further including a pneumatic system operatively connected to the one or more rollers, wherein the pneumatic system is configured to adjust the position of the one or more rollers.

4. The apparatus of claim 1, wherein the distance of the air gap is adjustable by changing the position of the thin foil relative to the substrate.

5. The apparatus of claim 1, wherein the distance of the air gap is adjustable by changing the position of both the thin foil and the substrate relative to each other.

6. The apparatus of claim 5, wherein adjustment of the distance of the air gap is determined based on at least one of an operating voltage for the electron beam generating assembly, a type of the substrate, a thickness of the substrate, or a speed at which the substrate is passed by the thin foil.

7. The apparatus of claim 1, further including a controller configured to:
control an operating voltage of the electron beam generating assembly; and
adjust the distance of the air gap based at least in part on the operating voltage.

8. The apparatus of claim 7, wherein the distance of the air gap is manually adjustable and the operating voltage is manually adjustable.

9. The apparatus of claim 7, wherein the controller is configured to receive input regarding the substrate and is configured to automatically adjust the operating voltage and the distance of the air gap based on the input.

10. The apparatus of claim 7, further including a temperature sensor configured to generate a signal indicative of an air temperature within the air gap, wherein the temperature sensor is configured to transmit the signal to the controller, and wherein the controller is configured to automatically adjust the distance of the air gap based on the signal.

11. The apparatus of claim 1, wherein the processing assembly includes a non-chill roll system having one or more rollers configured to pass the substrate by the thin foil parallel to the thin foil, and wherein the distance of the air gap is adjustable by changing the position of the one or more rollers relative to the thin foil.

12. The apparatus of claim 1, wherein the processing assembly includes a chill drum configured to pass the substrate by the thin foil, wherein the substrate contours to the arc of the chill drum as it passes by the thin foil, and the distance of the air gap is adjustable by changing the position of the chill drum.

13. A method of treating a substrate with an electron beam processing apparatus, comprising:
generating a plurality of electrons using an electron beam generating assembly by heating a filament located within a chamber of the assembly;
directing the plurality of electrons out of the chamber through a thin foil located within a foil support assembly;
passing the substrate into a processing assembly configured to pass the substrate by the thin foil so that the plurality of electrons penetrates the substrate and causes a chemical reaction on the substrate; and
adjusting a distance of an air gap located between the thin foil and the substrate.

14. The method of claim 13, wherein the processing assembly includes one or more rollers configuration to pass the substrate by the thin foil, and wherein adjusting the distance of the air gap includes adjusting the position of the one or more rollers relative to the thin foil.

15. The method of claim 14, wherein adjusting the positioning of the one or more rollers includes using a pneumatic system.

16. The method of claim 13, wherein adjusting the distance of the air gap includes changing the position of the thin foil relative to the substrate.

17. The method of claim 13, wherein adjusting the distance of the air gap is performed prior to a production run.

18. The method of claim 13, wherein the distance of the air gap is determined based on at least one of an operating voltage of the electron beam generating assembly, a type of the substrate, a thickness of the substrate, or a speed at which the substrate is passed by the thin foil.

19. The method of claim 13, further comprising:
adjusting an operating voltage of the electron beam generating assembly.

20. The method of claim 19, wherein adjusting the operating voltage and adjusting the distance of the air gap is controlled by a controller.

21. The method of claim 20, further comprising:
inputting a type of substrate into the controller, wherein the controller is configured to automatically adjust the operating voltage and the distance of the air gap.

22. The method of claim 20, further comprising:
measuring an air temperature within the air gap using a temperature sensor and communicating the air temperature to the controller, wherein adjusting the distance of the air gap is based at least in part on the air temperature.

23. The method of claim 13, wherein the processing assembly includes a non-chill roll system having one or more rollers configured to pass the substrate by the thin foil parallel to the thin foil, and wherein the distance of the air gap is adjustable by changing the position of the one or more rollers relative to the thin foil.

24. The method of claim 13, wherein the processing assembly includes a chill drum configured to pass the substrate by the thin foil, wherein the substrate contours to the arc of the chill drum as it passes by the thin foil, and the distance of the air gap is adjustable by changing the position of the chill drum.

25. An electron beam processing apparatus for treating a substrate, comprising:
an electron beam generating assembly configured to generate a plurality of electrons;
a foil support assembly configured to direct the plurality of electrons through a thin foil; and
a processing assembly configured to pass the substrate by the thin foil;
wherein an air gap located between the thin foil and the substrate is adjustable.

26. An electron beam processing apparatus for treating a substrate comprising an adjustable air gap.
